(19) United States
(12) Patent Application Publication
(10) Pub. No.: US 2023/0227998 A1
(43) Pub. Date: Jul. 20, 2023

(54) METHOD FOR ADJUSTING THERMAL FIELD OF SILICON CARBIDE SINGLE CRYSTAL GROWTH

(71) Applicant: NATIONAL CHUNG SHAN INSTITUTE OF SCIENCE AND TECHNOLOGY, Taoyuan City (TW)

(72) Inventors: HSUEH-I CHEN, Taoyuan City (TW); CHENG-JUNG KO, Taoyuan City (TW); CHIH-WEI KUO, Taoyuan City (TW); JUN-BIN HUANG, Taoyuan City (TW); CHIA-HUNG TAI, Taoyuan City (TW)

(21) Appl. No.: 17/579,604

(22) Filed: Jan. 20, 2022

(51) Int. Cl. C30B 29/36; H01L 21/205; H01L 21/02

(52) U.S. Cl. CPC C30B 29/36; H01L 21/205; H01L 21/02167; H01L 21/02656

(57) ABSTRACT

Provides a method for adjusting a thermal field of silicon carbide single crystal growth, and steps comprise: (A) screening a silicon carbide source, and filling into a bottom of a graphite crucible; (B) placing a guide inside the graphite crucible; (C) placing a rigid heat conductive material on the guide, so that a gap between the guide and a crucible wall of the graphite crucible is reduced; (D) fixing a seed crystal on a top of the graphite crucible; (E) placing the graphite crucible equipped with the silicon carbide source and the seed crystal in an induction high-temperature furnace used by physical vapor transport method; (F) performing a silicon carbide crystal growth process; and (G) obtaining a silicon carbide single crystal.

### BACKGROUND OF THE INVENTION

### 1. Field of the Invention

The present disclosure relates to a method for adjusting a thermal field of silicon carbide single crystal growth, and in particular to a method for adjusting a thermal field of silicon carbide single crystal growth by means of a rigid material to reduce a gap between a thin shell guide (hereinafter referred to as a guide) and a graphite crucible wall.

### 2. Description of the Related Art

With the development of science and technology, the specification demand for semiconductor materials is getting higher and higher, the semiconductor materials are evolved from the use demand of high power or broadband, for example, from the first generation of semiconductors mainly with materials of Si, Ge, to the second generation of semiconductors mainly with materials of GaAs, InP, up to now the third generation of semiconductors of wide bandgap materials of silicon carbide (SiC), GaN, Ga₂O₃, AlN, diamond, and the current most popular material on the market is the SiC substrate. SiC has excellent semiconductor characteristics such as high hardness, high breakdown electric field, high saturated electron mobility, and high bandgap, which is the first choice for high-power components or electric vehicle components.

In terms of use demand, SiC wafers are respectively semi-insulation (SI) and conductive type (N-type or P-type), the main commodities of top few large manufacturers in the world are wafers with four to six inches, some manufacturers have exhibited wafers with eight inches, but the catalog has not been listed as a standard commodity. These two types are respectively used in 5G communication and electric vehicle markets, and are also quite popular development objectives in the current market. The difference in specifications between the two types of wafers is mainly due to the different resistivity and crystal axial direction. There is a big problem in the process of crystal growth, which is the formation of defects around the crystal, resulting in a decrease in the usable area. At present, it has been set forth in the catalog of large factories that the cumulative defect area is ≤10 to 30% based on the difference in grade, and according to the practical experience of crystal growth, it shows that crystal defects can be divided into center and surrounding according to the location of occurrence, but most of them extend from the surrounding to the inside.

The main methods of single crystal SiC growth can be divided into liquid phase growth method and vapor growth method. The liquid phase growth method is just Czochralski growth method, but because the silicon carbide needs to be at a high temperature more than 3000K in order to reach its melting point, and the solubility of carbon in silicon is very low, the control is not easy, and the growth speed is quite slow, the method is not suitable for industrial production.

Vapor crystal growth method, in addition to the chemical vapor deposition (CVD) method, is mainly with Modified-Lely physical vapor transport (PVT), and the crystal growth furnace has two kinds of thermal resistance type and induction type, most of which are the latter. The general configuration is as shown in FIG. 1, wherein a silicon carbide seed crystal 1 is placed on a top of a graphite crucible 3, a silicon carbide source 2 is placed at a bottom of the graphite crucible 3, and then placed in an insulation material 4, and placed in the induction crystal growth furnace, heated by an induction coil 5 to 2000 to 2500° C., and the pressure is reduced below 50 torr, the silicon carbide source 2 is sublimated and crystallized to the silicon carbide seed crystal 1 by establishing a temperature gradient up and down within the graphite crucible 3.

Typical PVT methods perform SiC crystal growth, and as growing time passes by longer and longer, the methods usually encounter the following problems: there will be polycrystal overlays around the growing single crystals, so the part of guide 6 will be put in the graphite crucible. As shown in FIG. 2, the peripheral polycrystal is separated so that the crystal grows according to the path of the guide 6 to achieve the purpose of increasing a thickness of the crystal or expanding the crystal. Compared with the original situation where the guide 6 is not used, the peripheral polycrystal cannot enter, but the inside of the guide 6 also provides a platform for depositing polycrystal, thus affecting the growth of internal single crystals. Once polycrystals contact with single crystals in the growth process, there is a high chance that the edge of the single crystal will cause the lattice to twist or produce an angle grain boundary, affecting the usable region of the crystal, and even in the later stage of the slicing, grinding and polishing processes, there will be a risk of fragmentation. Therefore, it is a very important issue to avoid the production of polycrystals in the guide.

The physical vapor transport method is mainly under the condition of high temperature and low pressure to reach the sublimation point of SiC, and the SiC reaction gas sublimated from a solid to a gaseous state is deposited in a relative cold zone of the crucible 3, at this time, by controlling the thermal field, SiC is deposited in seed crystal 1, and SiC single crystal begins to grow. In order to achieve the purpose of increasing a thickness of the crystal or expanding the crystal, a guide 6 is usually introduced. The guide 6 itself is very easy to occur polycrystal deposition because of exposure to the reaction zone of SiC sublimation gas, and some researchers use protective coatings, such as TaC, NbC and other high-temperature ceramics to avoid deposition, but the insufficient adhesion of protective coatings and the guide 6 is still a major technical difficulty.

It is known that the SiC crystal growth method using a guide of a double-layer material divides the guide into two materials, of which an inner guide near the sublimation zone has a thermal conductivity >50 W/(m·K) and an outer guide has a thermal conductivity <20 W/(m·K). The purpose is to utilize materials with low thermal conductivity, which react more easily with corrosive gases than porous materials, thereby eliminating or avoiding corrosion of high thermal conductivity guide tubes (guides). In addition, because the sublimation vapor rich in silicon will react with a surface of the guide tube during growth, it results in an uneven surface and the quality of crystal edge growth is affected. The above-mentioned prior art can theoretically achieve the effect, but if the furnace body used by the PVT method is an induction heating furnace, it will have an adverse effect. Because induction heating (IH) is performed by an eddy current formed on the surface of the crucible, the heating source is the outer layer of the crucible, and the heat is transferred to the inside through heat conduction and thermal radiation, while the design of the double-layer guide tube hinders the transfer of heat to the inside to cause that the temperature of the guide is low, resulting in more polycrystal deposition, which has an adverse effect on subsequent single crystal growth.

In summary, the current thermal field adjustment of the silicon carbide single crystal growth by means of a guide will affect the internal single crystal growth state. Once polycrystals contact with single crystals in the growth process, there is a high chance that the edge of the single crystal will cause the lattice to twist or produce an angle grain boundary, affecting the usable region of the crystal, and even in the later stage of the slicing, grinding and polishing processes, there will be a risk of fragmentation. Therefore, the applicant in the application exhausted his mind to research carefully, and then developed a method for adjusting a thermal field of silicon carbide single crystal growth, effectively solving the problems encountered by single crystal growth.

### BRIEF SUMMARY OF THE INVENTION

In view of the disadvantages of the above-mentioned prior art, a main object of the present disclosure is to provide a method for adjusting a thermal field of silicon carbide single crystal growth. By means of quick heat transfer, the heat generated outside the crucible is introduced into the guide to reduce or avoid crystallization on the guide during growth, thereby increasing the usable region of the single crystal.

To achieve the above object, according to a solution provided by the present disclosure, it provides a method for adjusting a thermal field of silicon carbide single crystal growth, and steps comprise: (A) screening a silicon carbide source, and filling into a bottom of a graphite crucible; (B) placing a guide inside the graphite crucible; (C) placing a rigid heat conductive material on the guide, so that a gap between the guide and a crucible wall of the graphite crucible is reduced; (D) fixing a seed crystal on a top of the graphite crucible; (E) placing the graphite crucible equipped with the silicon carbide source and the seed crystal in an induction high-temperature furnace used by physical vapor transport method; (F) performing a silicon carbide crystal growth process; and (G) obtaining a silicon carbide single crystal.

Preferably, the rigid heat conductive material may be graphite, tantalum carbide (TaC), niobium carbide (NbC) or tungsten carbide (WC) of a high-temperature and low-pressure resistant material, thermal conductivity >10 W/m·K.

Preferably, the number of the rigid heat conductive materials is at least one or more, a geometric shape thereof is an axisymmetric geometric shape of disk or polygon.

Preferably, the number of the rigid heat conductive materials may be more than two, the rigid heat conductive materials may go with each other in different geometric shapes.

Preferably, a gap between the rigid heat conductive material and the crucible wall is ≤15 mm.

Preferably, a distance between a top of the rigid heat conductive material and a top of the guide may be 1 mm to 30 mm.

Preferably, the rigid heat conductive material has a thickness ≤15 mm.

The above summary description and the following detailed description and the accompanying drawings are the way, means and effect made for further describing the disclosure which can achieve a predetermined object. Other objects and advantages of the disclosure will become apparent from the following description and the drawings.

### BRIEF DESCRIPTION OF THE DRAWINGS

FIG. 1 is a schematic view of a graphite crucible of prior art.

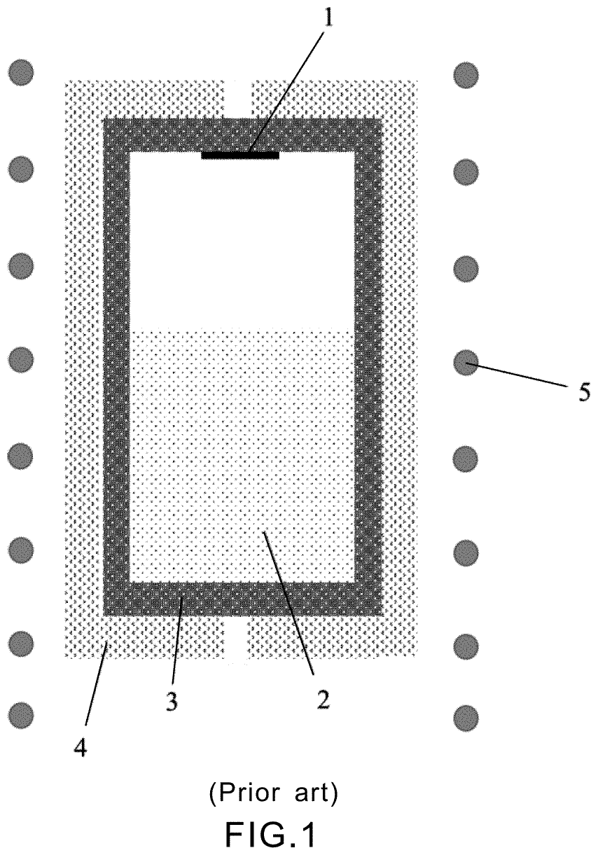

FIG. 2 is a schematic view of a guide of the graphite crucible of prior art.

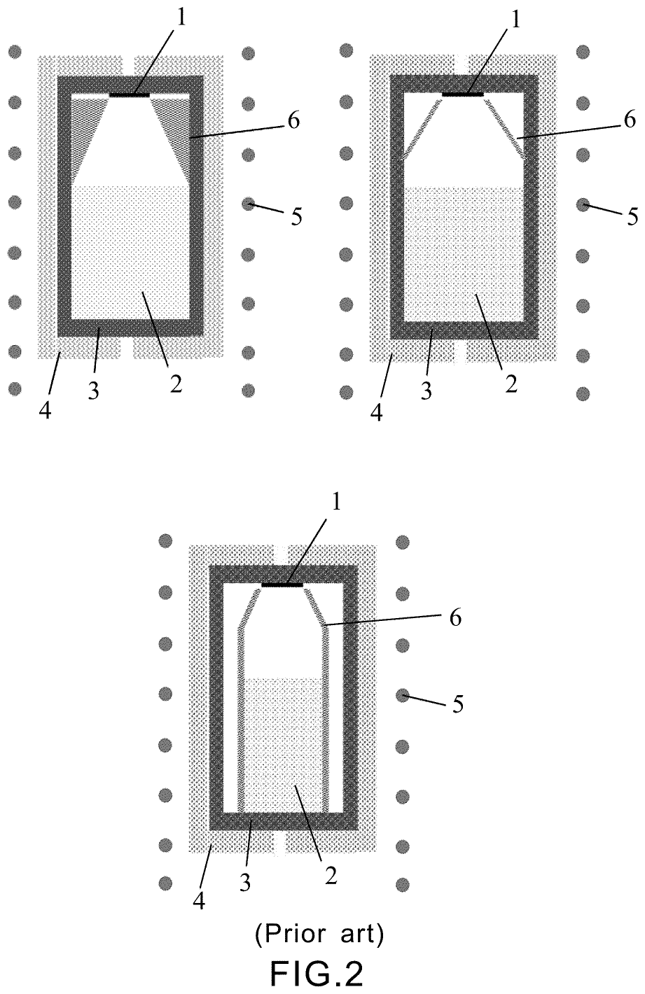

FIG. 3 is a schematic view of a graphite crucible of the silicon carbide crystal growth of the present disclosure.

FIG. 4 shows images of wafer testing of the present disclosure.

FIG. 5 is a flow chart of a method for adjusting a thermal field of silicon carbide single crystal growth of the present disclosure.

### DETAILED DESCRIPTION OF THE INVENTION

The implementation of the disclosure is further described by the specific embodiments as below, and a person having ordinary skill in the art can easily understand other advantages and effects of the present disclosure by the content of the specification.

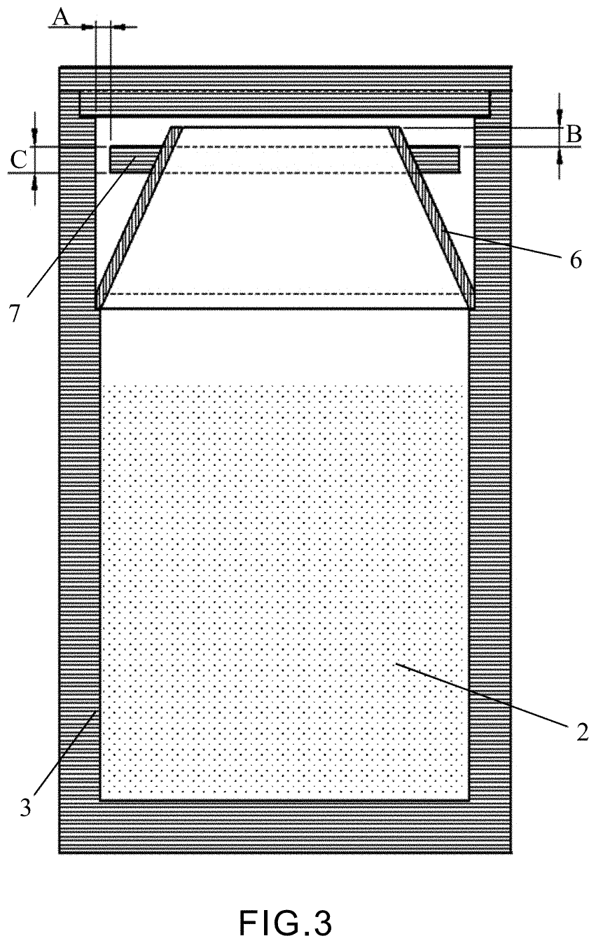

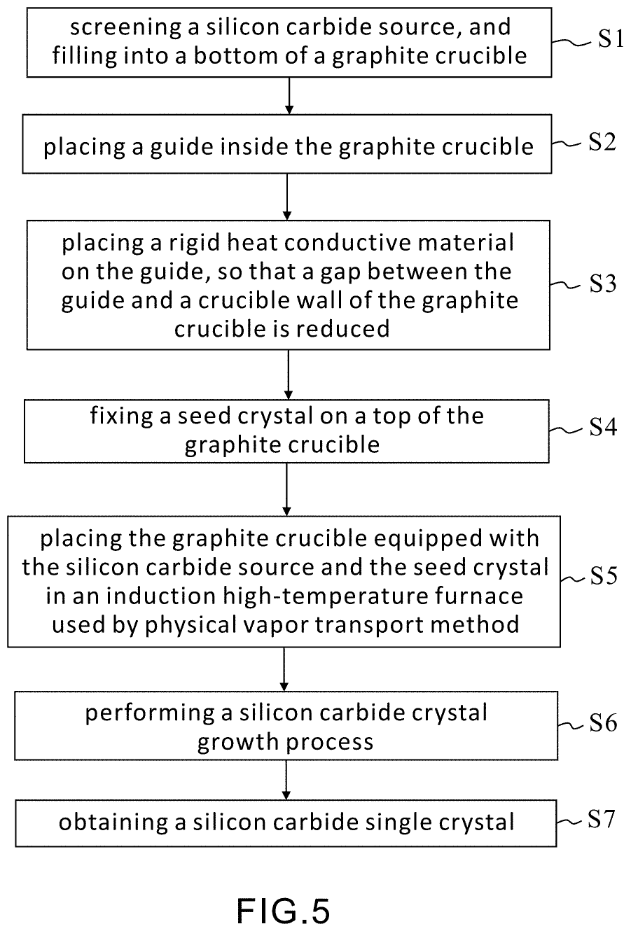

Referring to FIGS. 5 and 3, FIG. 5 is a flow chart of a method for adjusting a thermal field of silicon carbide single crystal growth of the present disclosure, FIG. 3 is a schematic view of a graphite crucible of the silicon carbide crystal growth of the present disclosure. The present disclosure is to provide a method for adjusting a thermal field of silicon carbide single crystal growth, steps comprising: step S1, screening a silicon carbide source 2, and filling into a bottom of a graphite crucible 3; step S2, placing a guide 6 inside the graphite crucible 3; step S3, placing a rigid heat conductive material 7 on the guide 6, so that a gap between the guide 6 and a crucible wall of the graphite crucible 3 is reduced; step S4, fixing a seed crystal 1 on a top of the graphite crucible 3; step S5, placing the graphite crucible 3 equipped with the silicon carbide source 2 and the seed crystal 1 in an induction high-temperature furnace used by physical vapor transport method; step S6, performing a silicon carbide crystal growth process; step S7, obtaining a silicon carbide single crystal.

In the embodiment, the rigid heat conductive material 7 may be graphite, tantalum carbide (TaC), niobium carbide (NbC) or tungsten carbide (WC) of a high-temperature and low-pressure resistant material, thermal conductivity >10 W/m·K. Further, the number of the rigid heat conductive materials 7 placed on the guide 6 may be at least one or more, a geometric shape thereof may be an axisymmetric geometric shape of disk or polygon. Moreover, if the number of the rigid heat conductive materials 7 placed on the guide 6 is more than two, the rigid heat conductive materials 7 may go with each other in different geometric shapes.

In the present embodiment, a gap A between the rigid heat conductive material 7 and the crucible wall of the graphite crucible 3 is ≤15 mm. Further, a distance between a top of the rigid heat conductive material 7 and a top of the guide 6 may be 1 mm to 30 mm. Moreover, the rigid heat conductive material 7 has a thickness ≤15 mm, the gap between the thin shell guide 6 and the crucible wall of the graphite crucible 3 can be reduced by the rigid heat conductive material 7, so that the thin shell guide 6 maintains a higher temperature, and reduces or avoids the deposition of polycrystal. Not only can it reduce the grain boundary defects extended by the silicon carbide polycrystal to make the usable area increase, but it can also be used in the expansion experiment in the future.

As stated above, the present disclosure uses the physical vapor transport method (PVT) for silicon carbide single crystal growth, and under the premise of induction heating in a crystal growth furnace, the thin shell guide 6 is used and a rigid heat conductive material 7 is used to connect to the heat source of the crucible wall, so that the heat transfer quickly gets to the guide 6, and the rigid heat conductive material 7 connecting the crucible wall and (graphite) guide 6 is adjusted according to different design needs of thermal field, including adjusting the material, size, geometry and contact area.

The present disclosure uses a SiC crystal growth furnace having an induction heating furnace body to perform SiC single crystal growth with the rigid heat conductive material 7 connecting to the thin shell guide 6 and graphite crucible wall, the rigid heat conductive material 7 may be metal, carbide, carbon material and other pure elements or compounds of a high-temperature and low-pressure resistant material. By means of quick heat transfer, the heat generated outside the crucible 3 is introduced into the guide 6 to reduce or avoid crystallization on the guide 6 during growth, thereby increasing the usable region of the single crystal.

The present disclosure uses induction heating technology for consideration to make alternating current of a specific frequency pass through a copper coil to produce an alternating magnetic field around the coil, using electromagnetic induction to make the crucible 3 produce eddy current to achieve the purpose of heating, and because of the influence of the skin effect, the eddy current is concentrated on the surface of the crucible 3. In other words, the heat source is concentrated on the surface of the crucible 3, and the crucible 3 is equipped with a thin shell guide 6 therein, the heat source is not easy to reach the guide 6, so the inventors of the present disclosure use the rigid heat conductive material 7 to connect the thin shell guide 6 and the crucible wall of the graphite crucible 3, so that the thin shell guide 6 maintains a higher temperature to reduce or avoid the deposition of polycrystals.

The present disclosure uses the rigid heat conductive material 7 to connect the thin shell guide 6, the rigid heat conductive material 7 must be able to withstand a high-temperature and low-pressure environment, such as graphite, tantalum carbide (TaC), niobium carbide (NbC) or tungsten carbide (WC) and the like; the connection method can be full contact, no contact, etc.; the geometric shape can vary according to the needs of use, but based on the principle of axisymmetric relationship. As shown in FIG. 3, gap A, distance B and thickness C are all adjustable dimensions.

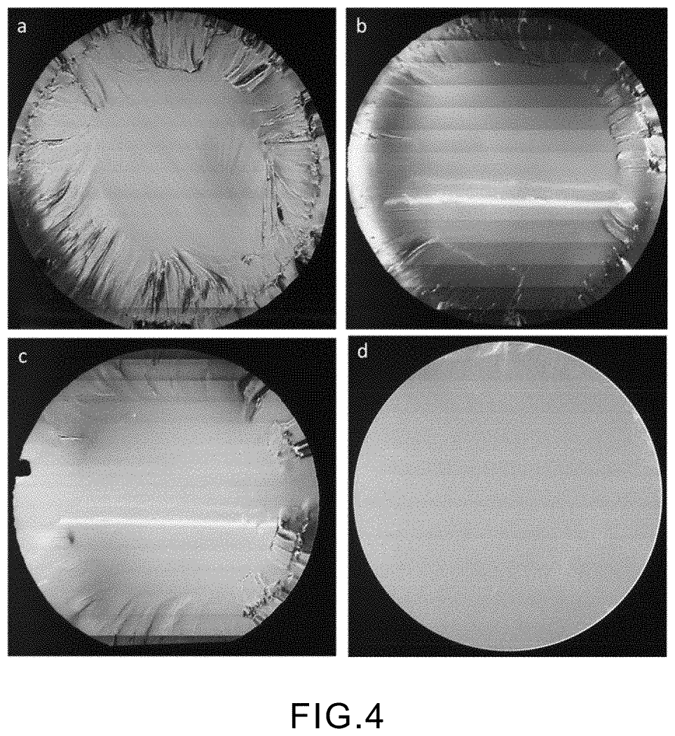

The present embodiment will compare four experiments, as shown in FIG. 4, respectively: (1) the upper left image (a) is a wafer produced by a normal (Normal) guide tube 6. (2) the upper right image (b) is a wafer produced by a heat conductive configuration guide pipe 6, the gap A, distance B and thickness C are all 8 mm, and the rigid heat conductive material 7 is graphite. (3) the lower left image (c) is a wafer produced by a heat conductive configuration guide pipe 6, the gap A=1 mm, the distance B=5 mm, the thickness C=1 mm, and the rigid heat conductive material 7 is TaC. (4) the lower right image (d) is a wafer produced by a heat conductive configuration guide pipe 6, the gap A=1 mm, the distance B=5 mm, the thickness C=5 mm, and the rigid heat conductive material 7 is graphite. These are respectively mounted on top of the graphite crucible 3 containing 3.5 kg of silicon carbide source 2, and an insulation material 4 is wrapped on the mounted graphite crucible 3, which is placed in a heating furnace for growth, growing at a temperature of 2100 to 2200° C., the pressure is 5 Torr, and after 100 hours of growth, each silicon carbide crystal with a thickness about 1.5 cm can be obtained.

Using the seed crystal of silicon carbide as the datum, a place going upwards 1 cm is cut therefrom, and the cut wafer is tested by X-Ray Topography (XRT) to observe the grain boundaries around the wafer. As shown in FIG. 4, the upper left image (a) is the wafer produced by the normal guide tube, and the gradual decrease of the surrounding defects can be observed from (a) to (d) in FIG. 4. Thus, the present disclosure may effectively improve wafer yield.

In summary, the present disclosure is a method for adjusting a thermal field of silicon carbide single crystal growth, configuration design is carried out regarding the physical vapor transport method, and induction heating technology and that the crucible 3 is equipped with a thin shell guide 6 therein are considered, so that the heat source concentrated on the surface of the crucible 3 can make the thin shell guide 6 maintain a higher temperature to reduce or avoid the deposition of polycrystal by using the rigid heat conductive material 7 to reduce the gap between the thin shell guide 6 and the crucible wall of the graphite crucible 3. Accordingly, not only can it reduce the grain boundary defects extended by the silicon carbide polycrystal to make the usable area increase, but it can also be used in the expansion experiment in the future.

The above embodiments of the disclosure made only by way of example to describe the feature and effect of the disclosure, and it should not be considered as the scope of substantial technical content is limited thereby. Various possible modifications and alternations of the embodiments could be carried out by the those of ordinary skill in the art without departing from the spirit and scope of the disclosure. Therefore, the scope of the disclosure is based on the appended claims.

What is claimed is:

1. A method for adjusting a thermal field of silicon carbide single crystal growth, steps comprising:
(A) screening a silicon carbide source, and filling into a bottom of a graphite crucible;
(B) placing a guide inside the graphite crucible;
(C) placing a rigid heat conductive material on the guide, so that a gap between the guide and a crucible wall of the graphite crucible is reduced;
(D) fixing a seed crystal on a top of the graphite crucible;
(E) placing the graphite crucible equipped with the silicon carbide source and the seed crystal in an induction high-temperature furnace used by physical vapor transport method;
(F) performing a silicon carbide crystal growth process; and
(G) obtaining a silicon carbide single crystal.

2. The method for adjusting a thermal field of silicon carbide single crystal growth according to claim 1, wherein the rigid heat conductive material is graphite, tantalum carbide (TaC), niobium carbide (NbC) or tungsten carbide (WC) of a high-temperature and low-pressure resistant material, thermal conductivity >10 W/m·K.

3. The method for adjusting a thermal field of silicon carbide single crystal growth according to claim 1, wherein the number of the rigid heat conductive materials is at least one or more, a geometric shape thereof is an axisymmetric geometric shape of disk or polygon.

4. The method for adjusting a thermal field of silicon carbide single crystal growth according to claim 3, wherein the number of the rigid heat conductive materials is more than two, the rigid heat conductive materials go with each other in different geometric shapes.

5. The method for adjusting a thermal field of silicon carbide single crystal growth according to claim 1, wherein a gap between the rigid heat conductive material and the crucible wall is ≤15 mm.

6. The method for adjusting a thermal field of silicon carbide single crystal growth according to claim 1, wherein a distance between a top of the rigid heat conductive material and a top of the guide is 1 mm to 30 mm.

7. The method for adjusting a thermal field of silicon carbide single crystal growth according to claim 1, wherein the rigid heat conductive material has a thickness ≤15 mm.
